(19) United States
(12) Patent Application Publication
(10) Pub. No.: US 2018/0107045 A1
(43) Pub. Date: Apr. 19, 2018

(54) DISPLAY PANEL AND DISPLAY DEVICE

(71) Applicant: BOE TECHNOLOGY GROUP CO., LTD., Beijing (CN)

(72) Inventors: Qian WANG, Beijing (CN); Xiaochuan CHEN, Beijing (CN); Wenqing ZHAO, Beijing (CN); Xiaochen NIU, Beijing (CN); Jian GAO, Beijign (CN); Zhaohui MENG, Beijing (CN)

(21) Appl. No.: 15/554,847

(22) PCT Filed: Feb. 7, 2017
(86) PCT No.: PCT/CN2017/073019

§ 371 Date: Aug. 31, 2017

(30) Foreign Application Priority Data
May 17, 2016 (CN) 201620448701.6

(51) Int. Cl. G02F 1/1339; G02F 1/1337; G02F 1/1343; G02F 1/1368; G02F 1/1362; H01L 27/12; G02F 1/1335

(52) U.S. Cl. CPC G02F 1/13394; G02F 1/1337; G02F 1/134336; G02F 1/1368; G02F 1/136286; G02F 2001/134372; G02F 1/133514; H01L 27/124; G02F 1/133512; G02F 1/133553; G02F 2201/123; H01L 27/1248

(57) ABSTRACT

A display panel and a display device are provided. The display panel includes an array substrate and a color film substrate forming a cell aligning structure, and a liquid crystal layer arranged between the array substrate and the color film substrate. The thickness of the liquid crystal layer is 1.5 um to 3 um. The disclosure reduces the thickness of the liquid crystal layer and greatly reduces the falling edge time of the display panel without greatly affecting the transmittance, thereby reducing the overall response time of the display panel. This can be particularly useful in situations where a moderate light transmittance is required.

### RELATED APPLICATIONS

The present application is the U.S. national phase entry of the international application PCT/CN2017/073019, with an international filing date of Feb. 7, 2017, which claims the benefit of Chinese Patent Application No. 201620448701.6, filed on May 17, 2016, the entire disclosures of which are incorporated herein by reference.

### TECHNICAL FIELD

The present invention relates to the field of liquid crystal display technology, and more particularly to a display panel and a display device.

### BACKGROUND

The thin film transistor liquid crystal display (referred to as TFT-LCD) has the characteristics of small size, low power consumption, no radiation, low manufacturing cost and so on, and dominates the current flat panel display market. The flat panel display device can be, for example, a liquid crystal television, a mobile phone, a personal digital assistant (PDA), a digital camera, a computer screen or a laptop screen.

Typically, the liquid crystal display device includes a housing, a liquid crystal display panel and a backlight module. The liquid crystal display panel and the backlight module are arranged in the housing. As a core component of the TFT-LCD, the liquid crystal display panel is mainly composed of a thin film transistor array substrate (TFT array substrate), a color filter substrate (CF) and a liquid crystal layer arranged between these two substrates. A cell aligning process is performed to prevent outflow of the liquid crystal between the array substrate and the color film substrate. Sealant is coated on the peripheral edges of the array substrate and the color film substrate to form a liquid crystal cell, thereby achieving liquid crystal light guide and display. A spacer is usually provided between the array substrate and the color film substrate to maintain the cell gap.

Liquid crystal is filled between the array substrate and the color film substrate, an electric field is applied to control liquid crystal deflection to control the light intensity, and the image to be expressed is displayed in combination with the function of the color film substrate. The distance between the array substrate and the color film substrate is the liquid crystal cell gap, which has an important influence on the liquid crystal display effect. Therefore, it is necessary to accurately control the liquid crystal cell gap during the cell aligning process of the liquid crystal display device.

Cell gap and pretilt angle are two important parameters affecting the performance of the liquid crystal display panel. The cell gap is the thickness of the liquid crystal layer arranged between the array substrate and the color film substrate, the cell gap affects the light transmittance of the liquid crystal display panel and the response time of the liquid crystal. In order to obtain a display effect of a high contrast, high brightness and high response speed, the cell gap should be controlled strictly.

At present, in the field of AR (augmented reality)/VR (virtual reality), there is a strict requirement on the response time of the liquid crystal display (gray response time GTG<3 ms). On the basis of the improvement of liquid crystal materials, the process should be optimized to cooperate with the improvement of the response time. The response time of liquid crystal can be divided into two parts: the rising edge time (Ton) mainly depends on the drive voltage, and the falling edge time (Toff) depends on the viscous force of the liquid crystal. Therefore, for the improvement of liquid crystal materials, Toff should be improved to reduce the response time. In the existing research, the transmittance of the liquid crystal cell is increased as much as possible, while the liquid crystal cell gap is ignored. A panel with a short LCD display response time and a moderate transmittance has a good market prospect, while there is no specific solution yet.

### SUMMARY

In view of the drawbacks of the prior art, an embodiment of the present invention provides a display panel and a display device, which reduces the thickness of the display panel, thereby reducing the response time of the liquid crystal.

In a first aspect, an embodiment of the present invention provides a display panel. The display panel includes an array substrate and a color film substrate, which form a cell aligning structure. A liquid crystal layer is arranged between the array substrate and the color film substrate. The thickness of the liquid crystal layer is 1.5 um to 3 um.

In certain exemplary embodiments, the thickness of the liquid crystal layer is 1.5 um.

In certain exemplary embodiments, a surface of the color film substrate facing the array substrate includes a plurality of mounting regions for arranging columnar spacers. The columnar spacers maintain the thickness of the display panel. The mounting region includes a recess structure for accommodating the columnar spacer.

In certain exemplary embodiments, the depth of the recess structure is 0.2 um-0.3 um.

In certain exemplary embodiments, the color film substrate includes a glass substrate, a black matrix, a color filter layer, a common electrode layer, and a liquid crystal molecule alignment layer. The color filter layer includes a columnar protrusion.

In certain exemplary embodiments, the color film substrate includes a black matrix, a color filter layer and a reflective layer formed on the array substrate. The black matrix includes an opening defining a sub-pixel region. The color filter layer and the reflective layer are located in the sub-pixel region, and the reflective layer is located on a side of the color filter layer facing the array substrate.

In certain exemplary embodiments, the array substrate includes a base substrate. The base substrate includes a plurality of transparent regions and a plurality of opaque regions. The plurality of transparent regions correspond to a plurality of pixel electrodes arranged in an array on the base substrate. The plurality of opaque regions correspond to a plurality of thin film transistors, data lines and gate lines arranged in an array on the base substrate. The array substrate further includes a transparent common electrode. A portion of the common electrode located in the opaque region is thicker than a portion of the common electrode located in the transparent region.

In certain exemplary embodiments, the array substrate is covered with a planarization layer, and an alignment film is arranged on the planarization layer. The planarization layer extends to a non-display area of the array substrate, and the thickness of the planarization layer is equal to or greater than a depth of a via hole located in the non-display area of the array substrate.

In certain exemplary embodiments, the array substrate includes a source electrode, a drain electrode and a pixel electrode arranged in the same layer. The pixel electrode, the source electrode and the drain electrode are manufactured with the same material. The thickness of the pixel electrode is smaller than the thickness of the source electrode and drain electrode, and a plurality of slits are formed on the pixel electrode.

In certain exemplary embodiments, the array substrate further includes a gate electrode and a common electrode arranged in the same layer. The common electrode and the gate electrode are manufactured with the same material. The thickness of the common electrode is smaller than the thickness of the gate electrode, and a plurality of slits are formed on the common electrode.

In a second aspect, the embodiment of the present invention further provides a display device including the above mentioned display panel.

The display panel and display device provided by the embodiment of the present invention reduce the thickness of the liquid crystal layer and greatly reduce the falling edge time of the display panel without greatly affecting the transmittance, thereby reducing the overall response time of the display panel.

### BRIEF DESCRIPTION OF THE DRAWINGS

In order to more clearly illustrate the technical solutions in embodiments of the invention or in the prior art, the appended drawings needed to be used in the description of the embodiments or the prior art will be introduced briefly in the following. Obviously, the drawings in the following description are only some embodiments of the invention, and for those of ordinary skills in the art, other drawings may be obtained according to these drawings under the premise of not paying out creative work.

FIG. 1 is a structural schematic diagram of a display panel according to an embodiment of the invention;

FIG. 2 is a schematic diagram of a relationship between optical phase retardation and transmittance according to an embodiment of the invention;

FIG. 3 is a structural schematic diagram of a color film substrate according to an embodiment of the present invention;

FIG. 4 is a structural schematic diagram of a color film substrate according to another embodiment of the present invention;

FIG. 5 is a structural schematic diagram of a color film substrate according to still another embodiment of the present invention;

FIG. 6 is a schematic diagram of a plane structure of an array substrate according to an embodiment of the present invention;

FIG. 7 is a structural schematic diagram of an array substrate according to an embodiment of the present invention;

FIG. 8 is a structural schematic diagram of an array substrate according to another embodiment of the present invention; and

FIG. 9 is a structural schematic diagram of an array substrate according to still another embodiment of the present invention.

### DETAILED DESCRIPTION OF THE INVENTION

In order to more clearly illustrate the purpose, technical solutions and advantages of the present invention, in the following, the technical solutions in the embodiments of the invention will be described clearly and completely in connection with the drawings in the embodiments of the invention. Obviously, the described embodiments are only part of the embodiments of the invention, and not all of the embodiments. Based on the embodiments in the invention, all other embodiments obtained by those of ordinary skills in the art under the premise of not paying out creative work pertain to the protection scope of the invention.

Currently, the thickness d of the liquid crystal layer in the available product of the fringe field switching technology (referred to as FFS) is generally 3.2˜3.5 um, and the response time is about 30 ms. FIG. 1 is a structural schematic diagram of a display panel according to an embodiment of the invention. The display panel includes an array substrate and a color film substrate, which form a cell aligning structure. A liquid crystal layer is arranged between the array substrate and the color film substrate. The thickness of the liquid crystal layer is 1.5 um to 3 um.

When the voltage applied to the liquid crystal changes, the time required for the liquid crystal to change the original arrangement is the response time. Response time is a performance parameter, which indicates the time for the liquid crystal changes from a full dark state to a full bright state, and then from the full bright state to the full dark state. The response time is measured by the rising edge time Ton and falling edge time Toff. The rising edge time Ton is the time required for the transmittance increases from the minimum to 90% of the maximum. The falling edge time Toff is the time required for the transmittance decreases from the maximum to 10% of the maximum.

The rising edge time of the liquid crystal can be calculated mainly by the formula (1).

$${T}_{on} = \frac{{γ}_{1}}{{ɛ}_{0} Δ z ( {E}^{2} - {E}_{th}^{2} )} \qquad ( 1 )$$

Ton denotes the rising edge time; γ₁ denotes the rotational viscosity coefficient of the liquid crystal; ∈₀ denotes the dielectric constant in vacuum; Δ∈=∈ₚₐᵣₐₗₗₑₗ-∈_{vertical}; ∈ₚₐᵣₐₗₗₑₗ denotes a component of the dielectric constant parallel to the direction vector of the liquid crystal; ∈_{vertical} denotes a component of the dielectric constant perpendicular to the direction vector of the liquid crystal; E denotes the applied electric field intensity; Eₜₕ² denotes the threshold electric field.

The falling edge time of the liquid crystal can be calculated mainly by the formula (2).

$${T}_{off} = \frac{{γ}_{1} {d}^{2}}{{π}^{2} {K}_{22}} \qquad ( 2 )$$

Toff denotes the falling edge time; γ₁ denotes the rotational viscosity coefficient of the liquid crystal; d denotes the thickness of the liquid crystal layer; K₂₂ denotes the torsion elastic constant.

A direct relationship between the response time of the liquid crystal and the thickness of the liquid crystal layer can be effectively obtained by the above analysis. By reducing the thickness d of the liquid crystal layer of the liquid crystal, the falling edge time Toff can be reduced effectively.

As shown in Table 1, the simulation software TechWiz simulates the response time of the liquid crystal MAT-995 with different liquid crystal layer thicknesses in FFS mode. As it can be seen, if the thickness of the liquid crystal layer is reduced from 2.0 um to 1.5 um, the rising edge time Ton and falling edge time Toff are both reduced.

TABLE 1
response time table for liquid crystal layers
with thicknesses of 2.0 um and 1.5 um

| | MAT-995 | |
|---|---|---|
| Thickness of liquid crystal layer: 2.0 um | | |
| Rising edge time Ton | 10.7 | ms |
| Falling edge time Toff | 3.8 | ms |
| Response time RT | 14.5 | ms |
| Thickness of liquid crystal layer: 1.5 um | | |
| Rising edge time Ton | 7.6 | ms |
| Falling edge time Toff | 2.3 | ms |
| Response time RT | 9.9 | ms |

As shown in Table 2, it can be seen that the liquid crystal layer thickness can be reduced to shorten the response time of the liquid crystal. However, according to the actual situation, the transmittance of the display panel should be taken into account.

TABLE 2
response time table for liquid crystal layers with different thicknesses
Normal MAT-11-1530 (γ58/4.2 V)

Thickness (um)

| | 3 | 2.8 | 2.6 | 2.4 | 2.2 | 2 |
|---|---|---|---|---|---|---|
| Ton (ms) | 7 | 6.4 | 5.7 | 5.1 | 4.5 | 4.1 |
| Toff (ms) | 4.6 | 4.1 | 3.6 | 3.1 | 2.6 | 2.2 |
| RT (ms) | 11.6 | 10.5 | 9.3 | 8.2 | 7.1 | 6.3 |

As shown in Table 3, although the decrease in the thickness of the liquid crystal layer is conducive to shorten the response time of the liquid crystal, the transmittance of the display panel (light efficiency) is sacrificed accordingly.

TABLE 3
measured light efficiency values of the liquid
crystal layers having different thicknesses
MAT-11-1530

| | | | | |
|---|---|---|---|---|
| Thickness of liquid | 1.5 | 2.0 | 2.5 | 3.0 |
| crystal layer(um) | | | | |
| Phase retardation (°) | 165 | 220 | 275 | 330 |
| Light efficiency | 21.21% | 34.63% | 47.92% | 61.20% |

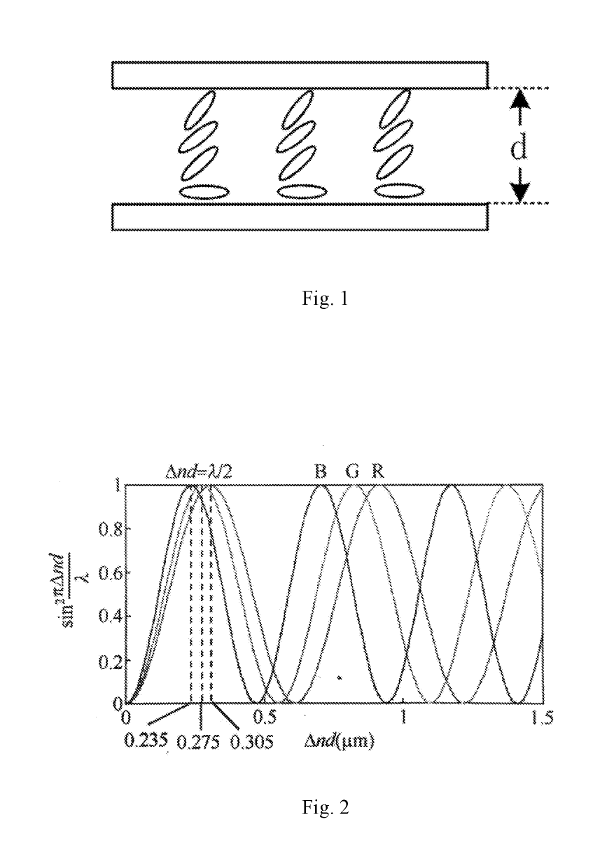

As shown in FIG. 2, from the relationship curve between And (corresponding to the thickness d of the liquid crystal layer) and sin²(πΔn×d/λ) (corresponding to the transmittance of the display panel), the transmittance of the display panel can be obtained, as shown in formula (3).

T=½×sin²2φ×sin²(πΔn×d/λ) (3)

T denotes the transmittance of the display panel; d denotes the thickness of the liquid crystal layer; φ denotes the azimuth angle of the liquid crystal (typically45°); λ is the wavelength; Δn is the birefringence.

As shown in FIG. 1, an embodiment of the present invention provides a display panel. The display panel includes an array substrate and a color film substrate, which form a cell aligning structure. A liquid crystal layer is arranged between the array substrate and the color film substrate. The thickness of the liquid crystal layer is 1.5 um to 3 um. As shown in FIG. 2, when the thickness of the liquid crystal layer in the display panel decreases to 1.5 um or less, the transmittance will continue to decline. Though only a moderate transmittance of the liquid crystal display is required in field of AR (augmented reality)/VR (virtual reality), the user perception and process characteristics should also be considered. As the thickness of the liquid crystal layer decreases, the uniformity of the photo spacers is deteriorated. Thus, in an embodiment of the present invention, the thickness of the liquid crystal layer is 1.5 um. In the embodiment of the present invention, the thickness of the display panel is reduced by the following embodiments.

### Embodiment 1

The display panel provided by the embodiment of the present invention includes a color film substrate. A surface of the color film substrate facing the array substrate includes a plurality of mounting regions for arranging columnar spacers. The columnar spacers maintain the thickness of the display panel. The mounting region includes a recess structure for accommodating the columnar spacer.

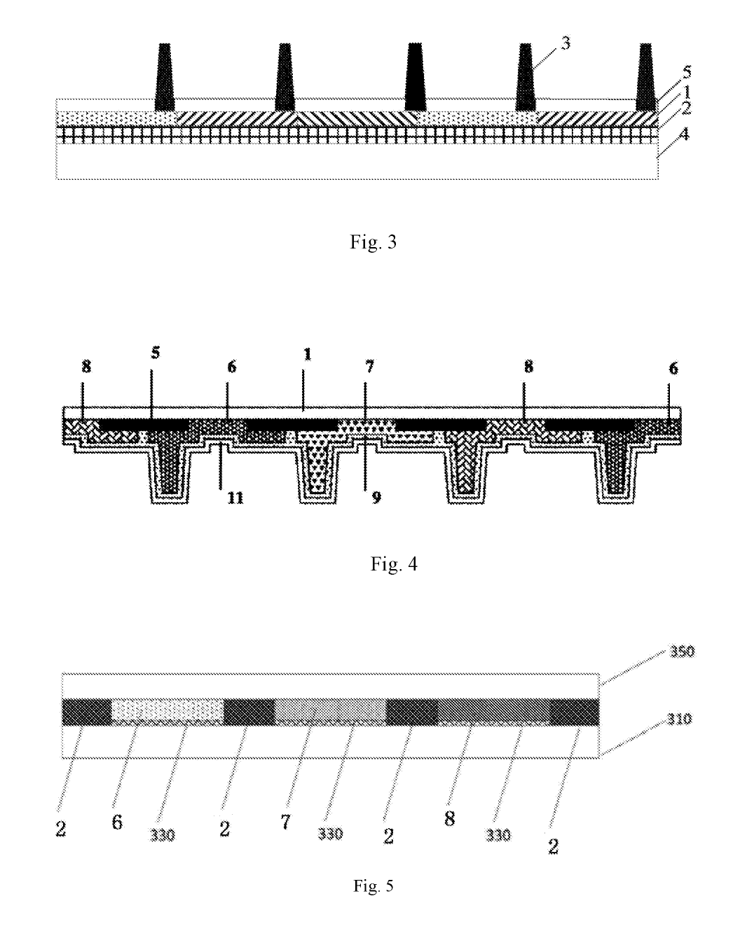

In particular, as shown in FIG. 3, the surface of the color film substrate facing the array substrate includes a plurality of mounting regions for arranging columnar spacers 3. The columnar spacers 3 maintain the thickness of the display panel. The mounting region includes a recess structure for accommodating the columnar spacer 3. A plurality of recess structures correspond to the positions of the columnar spacers. The depth of the recess structure can be 0.2 um-0.3 um.

The color film substrate provided in the embodiment of the present invention includes a substrate 4. A black matrix 2 is arranged on a surface of the substrate 4 facing the array substrate. Color filter units 1 are formed on the substrate with the black matrix. A planarization layer 5 is formed on the substrate with the color filter units. The planarization layer 5 includes a plurality of recess structures to accommodate the columnar spacers 3. Therefore, during subsequently forming the columnar spacers 3 on the color film substrate, it is only required that the columnar spacers 3 with the same height are inserted into the recess structures. In this way, the supporting force of the spacer is ensured. Moreover, a portion of the spacer is accommodated in the recess, reducing the thickness of the display panel.

### Embodiment 2

As shown in FIG. 4, the color film substrate provided by the embodiment of the present invention includes a glass substrate 1, a black matrix 5, a color filter layer 6-8, a common electrode layer 9, and a liquid crystal molecule alignment layer 11. The black matrix 5 is formed on the glass substrate 1. The color filter layer includes a plurality of columnar protrusions. The color filter layer covers the glass substrate 1 and the black matrix 5. The color filter layer includes a red pixel layer 6, a green pixel layer 7 and a blue pixel layer 8. The common electrode layer 9 is formed on the black matrix 5 and the color filter layer. The liquid crystal molecule alignment layer 11 is formed on the common electrode layer 9.

The columnar protrusions are formed on the color pixel photoresist, and the columnar protrusions are used as the columnar spacers between the array substrate and the color film substrate to maintain the thickness of the display panel. When the liquid crystal panel is subjected to external pressure, the thickness of the display panel can be maintained. The bonding area of the color pixel photoresist, the underlying glass substrate (i.e., the glass substrate on which the color filter substrate is formed) and the black matrix photoresist is far greater than the bonding area of the separately prepared columnar spacer and the underlying common electrode in the prior art. The bond between the color pixel photoresist, the underlying glass substrate and the black matrix photoresist is a bond between non-metallic materials, which has a bonding force stronger than the bonding force between the columnar spacer and the common electrode (i.e., between non-metallic material and metal material) in the prior art. Therefore, the parallel displacement of the columnar spacer under external pressure can be avoided, which is caused by the weak bonding force between the columnar spacer and the underlying common electrode layer in the prior art. Moreover, the large size and height of the separately prepared spacer for ensuring the supporting force of the spacer can also be avoided. In the embodiment of the present invention, the columnar protrusions formed on the color film substrate can replace the separately prepared spacer, ensuring the stability of the substrate and further reducing the size and height of the columnar spacer, and the thickness of the display panel is also reduced.

### Embodiment 3

An embodiment of the present invention provides a reflective display panel. In the reflective display panel, the color film substrate includes a black matrix 2, a color filter layer and a reflective layer 330 formed on the array substrate. The black matrix includes a plurality of openings defining a plurality of sub-pixel regions. The color filter layer and the reflective layer 330 are located in the sub-pixel region, and the reflective layer 330 is located on a side of the color filter layer facing the array substrate.

FIG. 5 is a structural schematic diagram of a color film substrate according to an embodiment of the present invention. As shown in FIG. 5, the color film array substrate includes an array substrate 310, a black matrix 2, a color filter layer 6-8 and a reflective layer 330 arranged on the array substrate 310. The black matrix 2 includes a plurality of openings defining a plurality of sub-pixel regions. The color filter layer 6-8 and the reflective layer 330 are located in the sub-pixel region, and the reflective layer 330 is located on a side of the color filter layer 6-8 facing the array substrate 310.

The sub-pixel region includes at least a red sub-pixel region, a green sub-pixel region and a blue sub-pixel region. Accordingly, the color filter layer also includes at least a red filter layer 6, a green filter layer 7 and a blue filter layer 8. That is, the upper portion of the red sub-pixel region is provided with a red filter layer 6, the upper portion of the green sub-pixel region is provided with a green filter layer 7, the upper portion of the blue sub-pixel region is provided with a blue filter layer 8. The lower portions of the red sub-pixel region, the green sub-pixel and the blue sub-pixel region are provided with a reflective layer 330. In addition, depending on the design requirements, the sub-pixel region can also include sub-pixel regions of other colors, such as a transparent sub-pixel region, a yellow sub-pixel region and so on. When sub-pixel regions of other colors are applied, the corresponding color filter layers can be provided accordingly. In the color film substrate and the display device of the embodiment of the present invention, the reflective layer is embedded in the sub-pixel region corresponding to the opening of the black matrix (i.e., the reflective layer is arranged in the same layer as the black matrix), thereby avoiding the separately arranged reflective layer. This configuration can effectively reduce the thickness of the reflective liquid crystal panel and the thickness of the display device, facilitating the thinning design of the reflective liquid crystal panel and the display device. Specifically, the thickness of the reflective layer 330 is greater than half the thickness of the color filter layer, and smaller than the thickness of the color filter layer. For example, if the thickness of the color filter layer is 2 um, the thickness of the reflective layer 330 can be in the range of 1 to 2 um.

### Embodiment 4

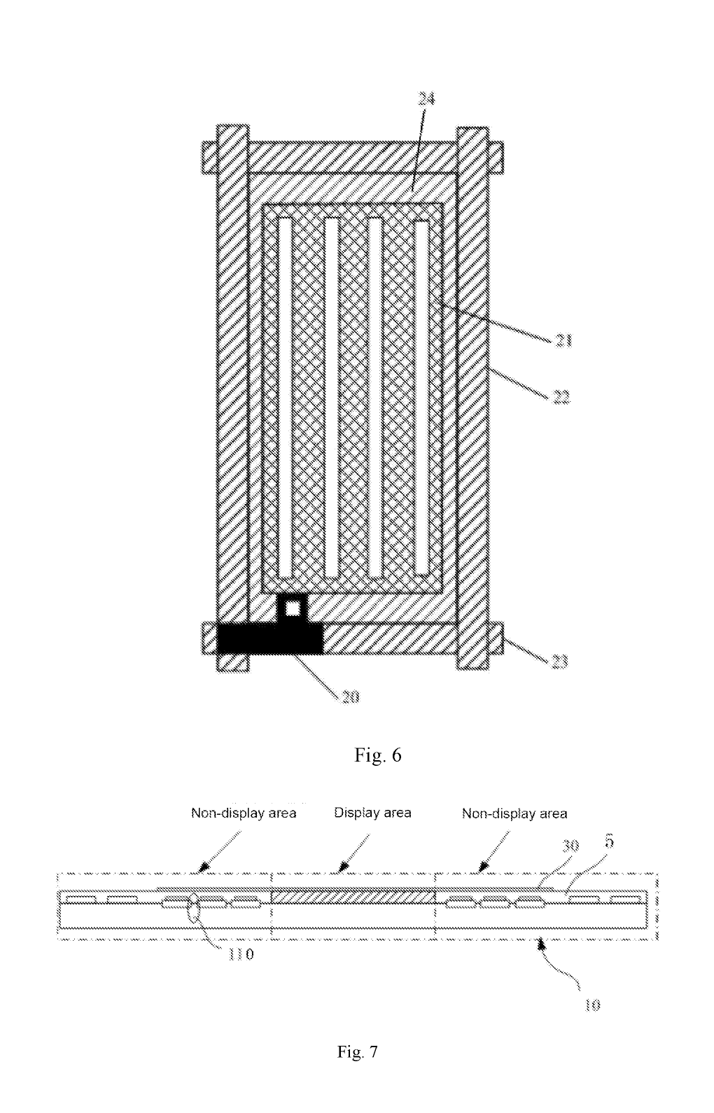

As shown in FIG. 6, a display panel according to an embodiment of the present invention includes an array substrate. The array substrate includes a base substrate (not shown). The base substrate includes a plurality of transparent regions and a plurality of opaque regions. The plurality of transparent regions correspond to a plurality of pixel electrodes 21 arranged in an array on the base substrate. The plurality of opaque regions correspond to a plurality of thin film transistors 20, data lines 22 and gate lines 23 arranged in an array on the base substrate. The array substrate further includes a transparent common electrode 24. A portion of the common electrode 24 located in the opaque region is thicker than a portion of the common electrode 24 located in the transparent region.

In an embodiment of the present invention, the common electrode 24 is a transparent conductive layer. In certain exemplary embodiments, the transparent conductive layer is a monolayer film of indium tin oxide (ITO) or indium zinc oxide (IZO), or a composite film of ITO and IZO. In an embodiment of the present invention, the common electrode of an ITO monolayer film will be described as an example. The greater the thickness of the ITO film, the smaller the square resistance of the ITO film. The smaller the thickness of the ITO film, the greater the transmittance of the ITO film. Therefore, the portion of the common electrode located in the opaque region has a small square resistance, and the portion of the common electrode located in the transparent region has a great transmittance. The common electrode in the embodiment of the present invention has different thicknesses respectively in the transparent region and the opaque region. The ITO resistance of the common electrode is lowered, the transmittance of light in the transparent area is not influenced, and the decrease in the thickness of the display panel has little influence on the transmittance of the display panel.

### Embodiment 5

As shown in FIG. 7, an embodiment of the present invention provides an array substrate 10. The array substrate 10 is covered with a planarization layer 5, and an alignment film 30 is arranged on the planarization layer 5. The planarization layer 5 extends to a non-display area of the array substrate 10, and the thickness of the planarization layer 5 is equal to or greater than a depth of a via hole 110 located in the non-display area of the array substrate.

In this embodiment, the planarization layer 5 is applied to shield the metal line and the via hole 110 located in the non-display area of the array substrate 10, so that the upper surface of the array substrate 10 is a flat plane (taking the placement direction of the array substrate 10 shown in FIG. 7 as a reference direction). The alignment liquid will not be affected by the via hole 110 when the alignment layer is formed, and the alignment liquid is spread uniformly. The problem of defects in the periphery of the formed alignment film 30 can thus be solved, the effect of forming the alignment film 30 can also be improved, thereby improving the display effect of the display device.

### Embodiment 6

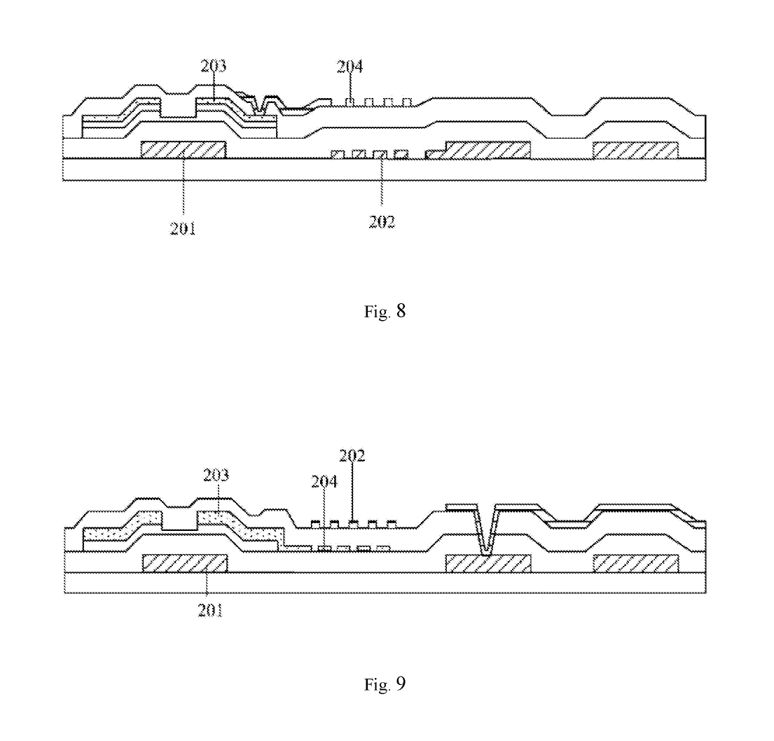

FIG. 8 and FIG. 9 are respectively structural schematic diagrams of array substrates according to the embodiments of the present invention, which differ in the positional relationship between the common electrode 202 and the pixel electrode 204. As shown in FIG. 8 or FIG. 9, the array substrate according to the embodiment of the present invention includes: a gate electrode 201 and a common electrode 202 arranged in the same layer. Alternatively, the array substrate includes a source electrode, a drain electrode 203 and a pixel electrode 204 arranged in the same layer. When the gate electrode 201 and the common electrode 202 are arranged in the same layer, the common electrode 202 and the gate electrode 201 can be manufactured with the same material. The thickness of the common electrode 202 is smaller than the thickness of the gate electrode 201, and a plurality of slits are formed on the common electrode 202. The transmittance of the common electrode 202 is higher than 30%. When the source electrode, the drain electrode 203 and the pixel electrode 204 are arranged in the same layer, the pixel electrode 204, the source electrode and the drain electrode 203 are manufactured with the same material. The thickness of the pixel electrode 204 is smaller than the thickness of the source electrode and drain electrode 203, and a plurality of slits are formed on the pixel electrode 204. The transmittance of the pixel electrode 204 is higher than 30%. The above mentioned two embodiments can ensure the transmittance of the display panel as much as possible while lowering the thickness of the display panel.

Since the gate electrode and the common electrode are made of the same material, the difficulty of the process can be reduced. The thickness of the common electrode is smaller than the thickness of the gate electrode, thus the transmittance of the common electrode can be ensured. Moreover, a one-time composition process using a two-tone mask can be applied to form the gate electrode and common electrode in the same layer, alternatively, a one-time composition process using a two-tone mask can be applied to form the source electrode, the drain electrode and the pixel electrode in the same layer, saving a mask, reducing the process complexity and process costs. The two-tone mask can be a halftone mask or a gray tone mask.

The embodiment of the present invention also provides a display device including the above mentioned display panel. The display device can be any product or component with display function, such as mobile phone, tablet computer, TV, display, notebook computer, digital photo frame and navigator. By applying the above mentioned display panel, the display device according to the embodiment of the present invention is thinner and more compact. Moreover, the response time of the liquid crystal can be greatly reduced in the application environment where a moderate light transmittance is required, which facilitates the operation of the display device in a dark environment.

In view of the above, the display panel and the display device provided by the embodiment of the present invention reduce the thickness of the liquid crystal layer and greatly reduce the falling edge time of the display panel without greatly affecting the transmittance, thereby reducing the overall response time of the display panel, and this can be particularly useful in situations where a moderate light transmittance is required.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto. Inventive embodiments may be practiced otherwise than as specifically described and claimed. Inventive embodiments of the present invention are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present invention.

All definitions, as defined and used herein, should be understood to control over dictionary definitions, definitions in documents incorporated by reference, and/or ordinary meanings of the defined terms.

The indefinite articles “a” and “an” as used herein in the specification and in the claims, unless clearly indicated to the contrary, should be understood to mean “at least one”.

The phrase “and/or” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of”, or, when used in the claims, “consisting of” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either”, “one of”, “only one of”, or “exactly one of”. “Consisting essentially of” when used in the claims, shall have its ordinary meaning as used in the field of patent law.

As used herein in the specification and in the claims, the phrase “at least one” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B”, or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising”, “including”, “carrying”, “having”, “containing”, “involving”, “holding”, “composed of” and the like are to be understood to be open-ended, i.e., to mean including but not limited to. Only the transitional phrases “consisting of” and “consisting essentially of” shall be closed or semi-closed transitional phrases, respectively.

Apparently, the person skilled in the art may make various alterations and variations to the invention without departing the spirit and scope of the invention. As such, provided that these modifications and variations of the invention pertain to the scope of the claims of the invention and their equivalents, the invention is intended to embrace these alterations and variations.

1. A display panel comprising: an array substrate and a color film substrate forming a cell aligning structure, a liquid crystal layer arranged between the array substrate and the color film substrate; wherein a thickness of the liquid crystal layer is 1.5 um to 3 um.

2. The display panel according to claim 1, wherein the thickness of the liquid crystal layer is 1.5 um.

3. The display panel according to claim 1, wherein a surface of the color film substrate facing the array substrate comprises a plurality of mounting regions for arranging columnar spacers maintaining a thickness of the display panel; the mounting region comprises a recess structure for accommodating the columnar spacer.

4. The display panel according to claim 3, wherein a depth of the recess structure is 0.2 um-0.3 um.

5. The display panel according to claim 1, wherein the color film substrate comprises a glass substrate, a black matrix, a color filter layer, a common electrode layer, and a liquid crystal molecule alignment layer; the color filter layer comprises a columnar protrusion.

6. The display panel according to claim 1, wherein the color film substrate comprises a black matrix, a color filter layer and a reflective layer formed on the array substrate; the black matrix comprises an opening defining a sub-pixel region; the color filter layer and the reflective layer are located in the sub-pixel region, and the reflective layer is located on a side of the color filter layer facing the array substrate.

7. The display panel according to claim 1, wherein the array substrate comprises a base substrate; the base substrate comprises a plurality of transparent regions and a plurality of opaque regions;
wherein the plurality of transparent regions corresponds to a plurality of pixel electrodes arranged in an array on the base substrate; the plurality of opaque regions correspond to a plurality of thin film transistors, data lines and gate lines arranged in an array on the base substrate;
and wherein the array substrate further comprises a transparent common electrode, wherein a portion of the common electrode located in the opaque region is thicker than a portion of the common electrode located in the transparent region.

8. The display panel according to claim 1, wherein the array substrate is covered with a planarization layer, an alignment film is arranged on the planarization layer; the planarization layer extends to a non-display area of the array substrate, and the thickness of the planarization layer is equal to or greater than a depth of a via hole located in the non-display area of the array substrate.

9. The display panel according to claim 1, wherein the array substrate comprises a source electrode, a drain electrode and a pixel electrode arranged in the same layer; the pixel electrode, the source electrode and the drain electrode are manufactured with the same material; the thickness of the pixel electrode is smaller than the thickness of the source electrode and drain electrode, and a plurality of slits are formed on the pixel electrode.

10. The display panel according to claim 1, wherein the array substrate further comprises a gate electrode and a common electrode arranged in the same layer; the common electrode and the gate electrode are manufactured with the same material; the thickness of the common electrode is smaller than the thickness of the gate electrode, and a plurality of slits are formed on the common electrode.

11. A display device comprising the display panel according to claim 1.

12. The display device according to claim 11, wherein the thickness of the liquid crystal layer is 1.5 um.

13. The display device according to claim 11, wherein a surface of the color film substrate facing the array substrate comprises a plurality of mounting regions for arranging columnar spacers maintaining a thickness of the display panel; the mounting region comprises a recess structure for accommodating the columnar spacer.

14. The display device according to claim 13, wherein a depth of the recess structure is 0.2 um-0.3 um.

15. The display device according to claim 11, wherein the color film substrate comprises a glass substrate, a black matrix, a color filter layer, a common electrode layer, and a liquid crystal molecule alignment layer; the color filter layer comprises a columnar protrusion.

16. The display device according to claim 11, wherein the color film substrate comprises a black matrix, a color filter layer and a reflective layer formed on the array substrate; the black matrix comprises an opening defining a sub-pixel region; the color filter layer and the reflective layer are located in the sub-pixel region, and the reflective layer is located on a side of the color filter layer facing the array substrate.

17. The display device according to claim 11, wherein the array substrate comprises a base substrate; the base substrate comprises a plurality of transparent regions and a plurality of opaque regions;
wherein the plurality of transparent regions correspond to a plurality of pixel electrodes arranged in an array on the base substrate; the plurality of opaque regions correspond to a plurality of thin film transistors, data lines and gate lines arranged in an array on the base substrate;
and wherein the array substrate further comprises a transparent common electrode, wherein a portion of the common electrode located in the opaque region is thicker than a portion of the common electrode located in the transparent region.

18. The display device according to claim 11, wherein the array substrate is covered with a planarization layer, an alignment film is arranged on the planarization layer; the planarization layer extends to a non-display area of the array substrate, and the thickness of the planarization layer is equal to or greater than a depth of a via hole located in the non-display area of the array substrate.

19. The display device according to claim 11, wherein the array substrate comprises a source electrode, a drain electrode and a pixel electrode arranged in the same layer; the pixel electrode, the source electrode and the drain electrode are manufactured with the same material; the thickness of the pixel electrode is smaller than the thickness of the source electrode and drain electrode, and a plurality of slits are formed on the pixel electrode.

20. The display device according to claim 11, wherein the array substrate further comprises a gate electrode and a common electrode arranged in the same layer; the common electrode and the gate electrode are manufactured with the same material; the thickness of the common electrode is smaller than the thickness of the gate electrode, and a plurality of slits are formed on the common electrode.
